(19) United States
(12) Patent Application Publication
(10) Pub. No.: US 2025/0015075 A1
(43) Pub. Date: Jan. 9, 2025

(54) SEMICONDUCTOR APPARATUS

(71) Applicant: ROHM CO., LTD., Kyoto (JP)

(72) Inventor: Kenichi YOSHIMURA, Kyoto-shi (JP)

(73) Assignee: ROHM CO., LTD., Kyoto (JP)

(21) Appl. No.: 18/896,701

(22) Filed: Sep. 25, 2024

Related U.S. Application Data
(63) Continuation of application No. PCT/JP2023/011425, filed on Mar. 23, 2023.

(30) Foreign Application Priority Data
Mar. 31, 2022 (JP) 2022-060579

(51) Int. Cl. H01L 27/02

(52) U.S. Cl. CPC H01L 27/0274

(57) ABSTRACT

A semiconductor device includes: first switching elements arranged in a first direction and each including a first gate wire extending in a second direction; and a back gate guard ring surrounding the first switching elements. The first switching elements are connected to each other in parallel and connected between a first pad and a second pad. The first switching elements include a driver switching element, the driver switching element being at least one first switching element located between two first end switching elements located at opposite ends of the first switching elements in the first direction. The first switching elements excluding the driver switching element include a first protection switching element, the first gate wire of the first protection switching element being connected to the first pad or the second pad.

### BACKGROUND

The present disclosure relates to a semiconductor device.

A conventional semiconductor device may include a protection circuit for electrostatic discharge (ESD). The protection circuit is formed of, for example, a metal-oxide-semiconductor field-effect transistor (MOSFET) (refer to, for example, Japanese Laid-Open Patent Publication No. 2014-241497).

### BRIEF DESCRIPTION OF DRAWINGS

FIG. 1 is a block diagram showing a schematic configuration of a first embodiment of a semiconductor device.

FIG. 2 is a circuit diagram of a driver switching element and a protection switching element shown in FIG. 1.

FIG. 3 is a circuit diagram of a driver switching element and a protection switching element shown in FIG. 1.

FIG. 4 is a schematic cross-sectional view showing operation of a protection element.

FIG. 5 is a schematic plan view of the driver switching element and the protection switching element shown in FIG. 2.

FIG. 6 is a schematic cross-sectional view taken along line F6-F6 in FIG. 5 showing operation of a first switching element in the semiconductor device of FIG. 1.

FIG. 7 is a schematic cross-sectional view showing operation of first switching elements of a semiconductor device in a comparative example.

FIG. 8 is a block diagram showing a second embodiment of a semiconductor device.

FIG. 9 is a circuit diagram of a driver switching element and a protection switching element shown in FIG. 8.

FIG. 10 is a circuit diagram of a driver switching element and a protection switching element shown in FIG. 8.

FIG. 11 is a schematic plan view of the driver switching element and the protection switching element shown in FIG. 9.

FIG. 12 is a circuit diagram of a driver switching element and a protection switching element in a modified example.

FIG. 13 is a circuit diagram of a driver switching element and a protection switching element in a modified example.

### DETAILED DESCRIPTION

Embodiments of a semiconductor device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure. In the present disclosure, the terms “first,” “second,” “third,” and the like are used to distinguish objects and are not used to give priority to one object.

This detailed description provides a comprehensive understanding of the methods, apparatuses, and/or systems described. Exemplary embodiments may have different forms, and are not limited to the examples described.

In this specification, “at least one of A and B” should be understood to mean “only A, or only B, or both A and B.”

### First Embodiment

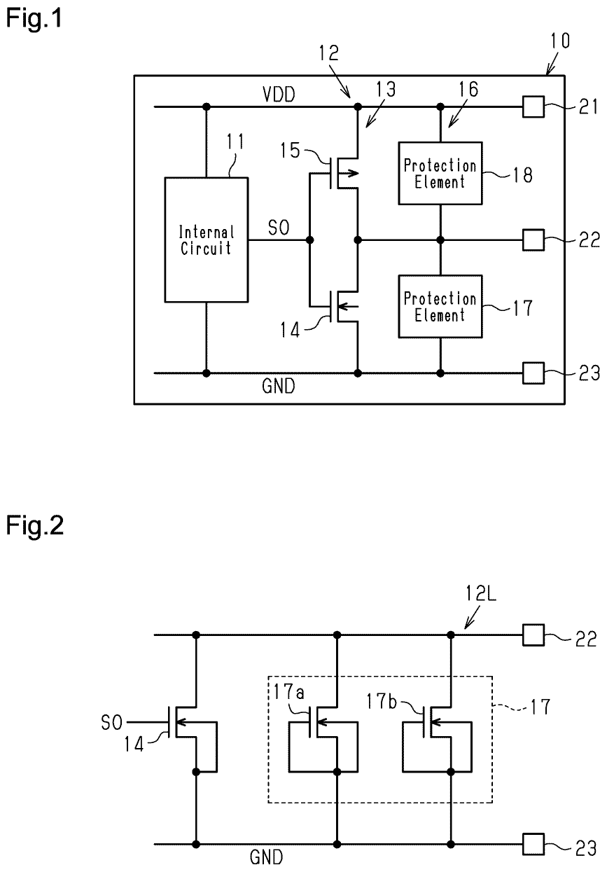

The first embodiment will now be described with reference to FIGS. 1 to 6.

### General Configuration of Semiconductor Device

As shown in FIG. 1, a semiconductor device 10 includes an internal circuit 11 and an output circuit 12. The semiconductor device 10 includes an output pad 22 corresponding to a first pad, a power pad 21 corresponding to a second pad, and a ground pad 23.

The internal circuit 11 includes a logic circuit that operates for the function of the semiconductor device 10. The internal circuit 11 is connected between the power pad 21 and the ground pad 23. The power pad 21 is configured to supply power voltage VDD from the outside of the semiconductor device 10. The ground pad 23 is configured to be connected to ground potential GND. The internal circuit 11 operates when the power voltage VDD is supplied. The internal circuit 11 outputs an output signal SO in accordance with a logic operation.

The internal circuit 11 includes an output terminal connected to the output pad 22 by the output circuit 12. The output pad 22 is configured to be connected to another semiconductor device or the like. The output circuit 12 is configured to output an output signal OUT to the output pad 22, which corresponds to the first pad. In the first embodiment, the output circuit 12 outputs the output signal OUT in response to the output signal SO.

The output circuit 12 includes an output buffer circuit 13 and a protection circuit 16.

The output buffer circuit 13 includes a first driver switching element 14 and a second driver switching element 15. The first driver switching element 14 and the second driver switching element 15 are each formed of a MOS transistor (MOSFET). In the first embodiment, the first driver switching element 14 is an N-channel MOS transistor (hereafter, referred to as “NMOS transistor”). In the first embodiment, the second driver switching element 15 is a P-channel MOS transistor (hereafter, referred to as “PMOS transistor”). In the first embodiment, the output buffer circuit 13 is a CMOS inverter circuit.

The first driver switching element 14 is connected between the output pad 22 and the ground pad 23. The first driver switching element 14 includes a source terminal connected to the ground pad 23. The first driver switching element 14 includes a drain terminal connected to the output pad 22. The first driver switching element 14 includes a gate terminal (control terminal) configured to receive the output signal SO.

The second driver switching element 15 is connected between the power pad 21 and the output pad 22. The second driver switching element 15 includes a source terminal connected to the power pad 21. The second driver switching element 15 includes a drain terminal connected to the output pad 22. The second driver switching element 15 includes a gate terminal (control terminal) configured to receive the output signal SO.

The protection circuit 16 includes a first protection element 17 and a second protection element 18. The first protection element 17 is connected between the output pad 22 and the ground pad 23. The second protection element 18 is connected between the power pad 21 and the output pad 22. The first protection element 17 and the second protection element 18 protect the internal circuit 11 from an ESD current flowing to the power pad 21 and the output pad 22.

FIG. 1 shows a single output pad 22, and the output buffer circuit 13 and the protection circuit 16 that are connected to the output pad 22. The semiconductor device 10 may include multiple output pads 22. The semiconductor device 10 may include one or more input pads. The semiconductor device 10 may be configured to receive a signal from the output pad 22. In this configuration, the output pad 22 is used as an input/output pad (I/O pad).

### Schematic Configuration of Driver Transistor and Protection Element

As shown in FIG. 2, the first driver switching element 14 is an NMOS transistor. The first driver switching element 14 is connected between the output pad 22 and the ground pad 23. The first driver switching element 14 includes a back gate terminal connected to the ground pad 23. That is, the back gate terminal of the first driver switching element 14 is connected to the source terminal of the first driver switching element 14.

The first protection element 17 includes a first protection switching element 17a and a second protection switching element 17b. The first protection switching element 17a and the second protection switching element 17b are each an NMOS transistor. The first protection switching element 17a includes a source terminal connected to the ground pad 23. The first protection switching element 17a includes a drain terminal connected to the output pad 22. The first protection switching element 17a includes a gate terminal and a back gate terminal that are connected to the source terminal of the first protection switching element 17a. The second protection switching element 17b includes a source terminal connected to the ground pad 23. The second protection switching element 17b includes a drain terminal connected to the output pad 22. The second protection switching element 17b includes a gate terminal and a back gate terminal that are connected to the source terminal of the second protection switching element 17b.

The first driver switching element 14 and the first protection element 17 form a first output circuit 12L connected between the output pad 22 and the ground pad 23. The first output circuit 12L is switched on and off based on the output signal SO to draw in current from the output pad 22 toward the ground pad 23.

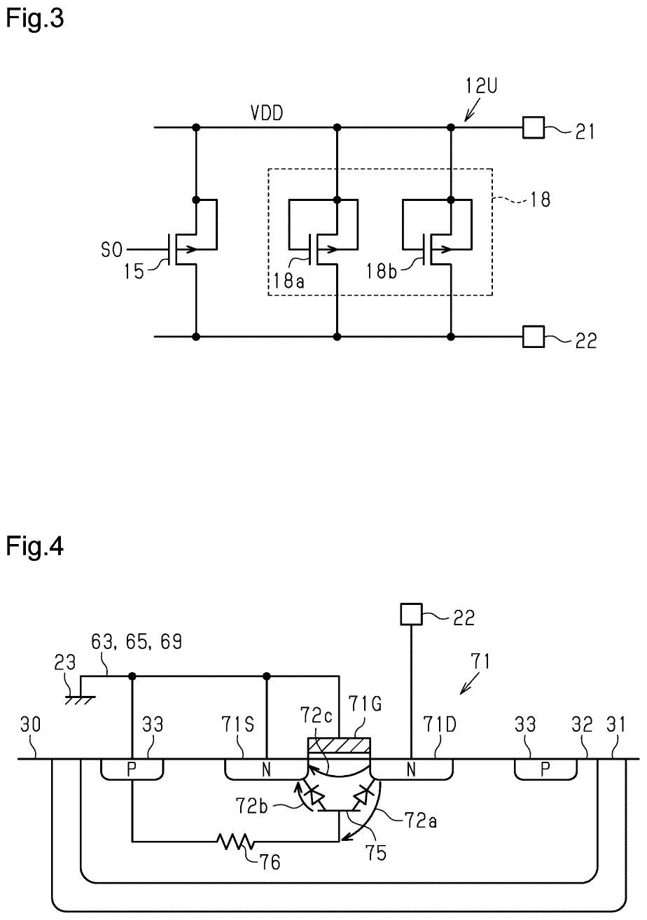

As shown in FIG. 3, the second driver switching element 15 is a PMOS transistor. The second driver switching element 15 is connected between the power pad 21 and the output pad 22. The second driver switching element 15 includes a back gate terminal connected to the power pad 21. That is, the back gate terminal of the second driver switching element 15 is connected to the source terminal of the second driver switching element 15.

The second protection element 18 includes a third protection switching element 18a and a fourth protection switching element 18b. The third protection switching element 18a and the fourth protection switching element 18b are each a PMOS transistor. The third protection switching element 18a includes a source terminal connected to the power pad 21. The third protection switching element 18a includes a drain terminal connected to the output pad 22. The third protection switching element 18a includes a gate terminal and a back gate terminal that are connected to the source terminal of the third protection switching element 18a. The fourth protection switching element 18b includes a source terminal connected to the power pad 21. The fourth protection switching element 18b includes a drain terminal connected to the output pad 22. The fourth protection switching element 18b includes a gate terminal and a back gate terminal that are connected to the source terminal of the fourth protection switching element 18b.

The second driver switching element 15 and the second protection element 18 form a second output circuit 12U connected between the power pad 21 and the output pad 22. The second output circuit 12U is switched on and off based on the output signal SO to draw in current from the power pad 21 toward the output pad 22.

### Configuration of Driver Switching Element and Protection Switching Element

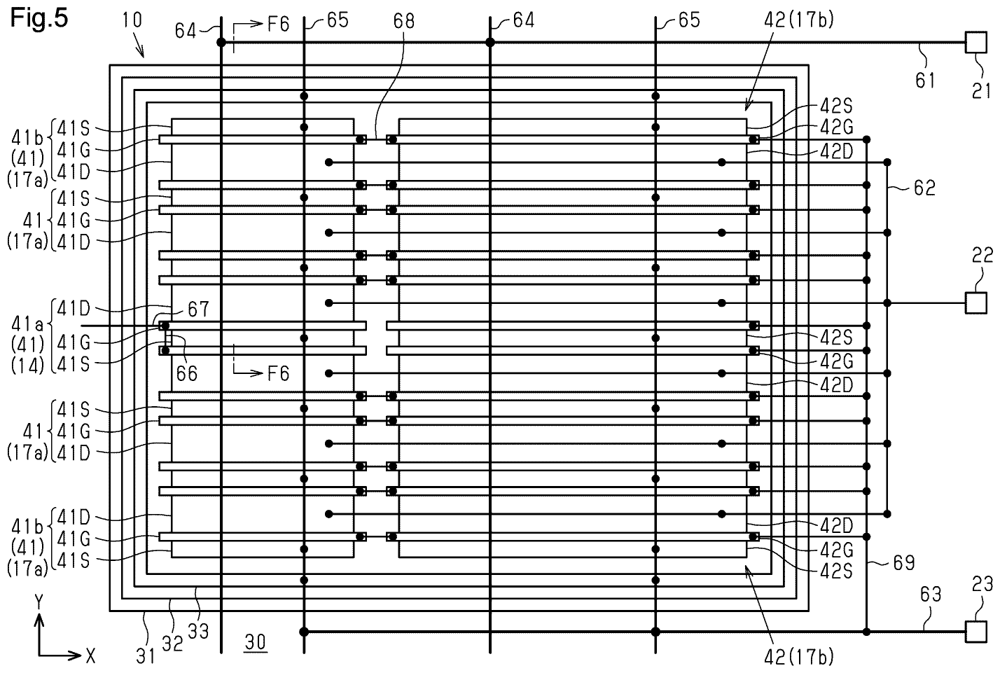

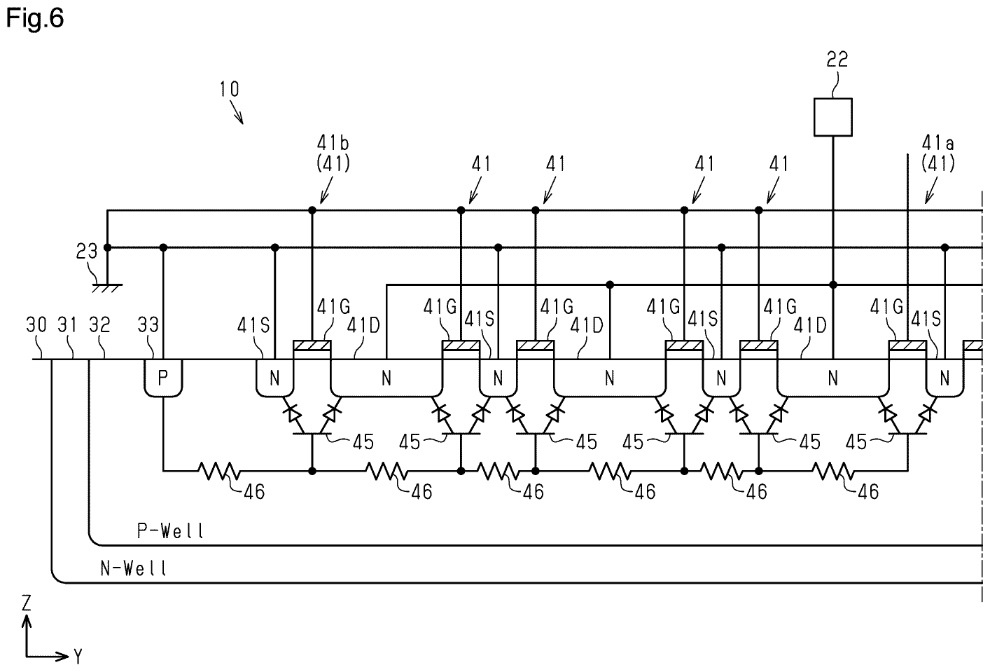

FIG. 5 is a plan view of a portion of the semiconductor device 10 shown in FIG. 1 showing a schematic structure of the first driver switching element 14 and the first protection element 17 (the first protection switching element 17a and the second protection switching element 17b) shown in FIG. 2. FIG. 6 is a cross-sectional view of a portion of the semiconductor device 10 showing a schematic structure of a first well region 31, a second well region 32, a back gate guard ring 33, and a first switching element 41 shown in FIG. 5. In FIG. 5 and other drawings, a solid line indicates a wire that connects an element or the like. A black dot indicates a contact.

The semiconductor device 10 includes a semiconductor substrate 30. The first driver switching element 14 and the first protection element 17, which are shown in FIG. 1, are formed on the semiconductor substrate 30. More specifically, FIG. 5 is a plan view of the semiconductor substrate 30 taken in a thickness-wise direction. In the description hereafter, the thickness-wise direction of the semiconductor substrate 30 is referred to as a “Z-direction.” Two directions that are orthogonal to each other and the Z-direction are referred to as an “X-direction” and a “Y-direction.” In the first embodiment, the X-direction corresponds to a “second direction.” The Y-direction corresponds to a “first direction.”

As shown in FIGS. 5 and 6, the semiconductor device 10 includes an N-type first well region 31. As viewed in the Z-direction, the first well region 31 is rectangular and elongated in the X-direction. A P-type second well region 32 is formed in the first well region 31. As viewed in the Z-direction, the second well region 32 is rectangular and elongated in the X-direction. The P-type back gate guard ring 33 is formed in the second well region 32. As shown in the Z-direction, the back gate guard ring 33 has the form of a rectangular frame that is elongated in the X-direction. The back gate guard ring 33 is connected to the ground pad 23 by wires 65 and 63.

As shown in FIG. 5, wires 64 and 61 are connected to the power pad 21. The wires 64 and 61 are configured to supply the power voltage VDD from the power pad 21 to, for example, the internal circuit 11 and the second output circuit 12U, shown in FIG. 1.

As shown in FIG. 5, the first switching elements 41 and second switching elements 42 are disposed at an inner side of the back gate guard ring 33. The second well region 32 and the back gate guard ring 33 form back gate terminals of the first switching elements 41 and the second switching elements 42. The first switching elements 41 include the first driver switching element 14 and the first protection switching element 17a, which are shown in FIG. 2. The second switching elements 42 each include the second protection switching element 17b, which is shown in FIG. 2.

The first switching elements 41 are arranged in the Y-direction. In the same manner, the second switching elements 42 are arranged in the Y-direction. The second switching elements 42 are arranged next to the first switching elements 41 in the X-direction.

The first switching elements 41 are formed of MOSFETs (NMOS transistors). Each of the first switching elements 41 includes a first gate wire 41G extending in the X-direction. Each of the first switching elements 41 includes an N-type first source region 41S and a first drain region 41D located at opposite sides of the first gate wire 41G. In two of the first switching elements 41 located adjacent to each other in the Y-direction, the first drain regions 41D are disposed so as to be continuous with each other.

The second switching elements 42 are formed of MOSFETs (NMOS transistors). Each of the second switching elements 42 includes a second gate wire 42G extending in the X-direction. Each of the second switching elements 42 includes an N-type second source region 42S and a second drain region 42D located at opposite sides of the second gate wire 42G. In two of the second switching elements 42 located adjacent to each other in the Y-direction, the second drain regions 42D are disposed so as to be continuous with each other.

The first gate wires 41G differ from the second gate wires 42G in length in the X-direction. In the first embodiment, the second gate wires 42G are set to be greater in length in the X-direction than the first gate wires 41G. The length of the first gate wire 41G in the X-direction is set in accordance with the gate width of the first switching element 41. The length of the second gate wire 42G in the X-direction is set in accordance with the gate width of the second switching element 42. Therefore, the gate width of the second switching element 42 is set to be greater than the gate width of the first switching element 41. The first drain regions 41D of the first switching elements 41 and the second drain regions 42D of the second switching elements 42 are connected to the output pad 22 by a wire 62. The first source regions 41S of the first switching elements 41 and the second source regions 42S of the second switching elements 42 are connected to the ground pad 23 by the wires 65 and 63.

Of the first switching elements 41, the two located at opposite ends in the Y-direction are referred to as two first end switching elements 41b. The first driver switching element 14 shown in FIG. 2 includes at least one of the first switching elements 41 that are located between the two first end switching elements 41b. It is preferred that the first driver switching element 14 is formed of a switching element 41 located at the center in the Y-direction among the first switching elements 41. In the first embodiment, the first driver switching element 14 is formed of two first switching elements 41a that are located at the center in the Y-direction among the first switching elements 41. The first driver switching element 14 may be formed of one or three or more first switching elements 41.

The first gate wires 41G of the two first switching elements 41a are connected to each other by a wire 66 and connected to the internal circuit 11, shown in FIG. 1, by a wire 67. As described above, the first driver switching element 14 shown in FIG. 2 is formed of the two first switching elements 41a shown in FIG. 5. In other words, the first switching element 41a is the first driver switching element 14.

The first gate wires 41G of the first switching elements 41 excluding the two first switching elements 41a are arranged next to the second gate wires 42G of the second switching elements 42 in the X-direction and respectively connected to the second gate wires 42G by wires 68. The second gate wires 42G of all of the second switching elements 42 are connected to the ground pad 23 by wires 69 and 63. More specifically, the first gate wires 41G of the first switching elements 41 excluding the two first switching elements 41a are connected to the ground pad 23. Thus, all of the second switching elements 42 form the second protection switching element 17b shown in FIG. 2. In other words, the second switching elements 42 are the second protection switching elements 17b. The first switching elements 41 excluding the two first switching elements 41a, which form the first driver switching element 14, form the first protection switching element 17a shown in FIG. 2. In other words, the first switching elements 41 excluding the first switching element 41a are the first protection switching elements 17a.

In the example shown in FIG. 5, the first gate wires 41G of the two first switching elements 41a are connected by the wires 66 and 67 to the internal circuit 11, which is shown in FIG. 1. The first switching elements 41 have the same electrical characteristics. Thus, the number of first switching elements 41 that are connected to the internal circuit 11 may be changed based on the design (layout) of the wires 66 and 67. The number of first switching elements 41 connected to the internal circuit 11 corresponds to the amount of current flowing from the output pad 22 toward the ground pad 23. The amount of current corresponds to, for example, the number of elements that are connected to the output pad 22 and configured to be driven by the first driver switching elements 14. Thus, the first switching elements 41 are configured to set the driving capacity of the first driver switching element 14 based on the number of first switching elements 41 connected to the wires 66 and 67.

Examples of setting of driving capacity based on the number of first switching elements 41a, other than the configuration shown in FIG. 5, will now be described. In a first example of the setting of driving capacity, for example, the first driver switching element 14 may be formed of a single first switching element 41a connected to the wire 67. In a second example of the setting of driving capacity, the first driver switching element 14 may be formed of four first switching elements 41a connected to the wires 66 and 67. By contrast, in the first switching element 41 that is not connected to the wire 67, the first gate wire 41G is connected to the ground pad 23. This forms the first protection switching element 17a. The first switching element 41a, which is connected to the wire 67, is formed in the same second well region 32 as the other first switching elements 41. Thus, the first switching element 41a is used as a protection switching element. More specifically, the first switching elements 41 are used as both the first driver switching element 14 and the first protection switching element 17a. On the other hand, all of the second switching elements 42 are dedicated switching elements that form the second protection switching element 17b.

The first driver switching element 14 and the first protection element 17 (the first protection switching element 17a and the second protection switching element 17b) shown in FIGS. 1 and 2 have been described. The second driver switching element 15 and the second protection element 18, which are shown in FIGS. 1 and 3, are configured in the same manner as the first driver switching element 14 and the first protection element 17. For example, the semiconductor device 10 includes third switching elements and fourth switching elements formed in an N-type third well region. The third well region, the third switching elements, and the fourth switching elements are configured in the same manner as the second well region 32, the first switching element 41, and the second switching elements 42, which are described above, except for conductivity type.

### Operation

The semiconductor device 10 of the first embodiment will now be described.

Operation of Protection Switching Element

Operation of one protection switching element will now be described.

FIG. 4 shows one protection switching element 71. The protection switching element 71 is formed in the P-type second well region 32. The protection switching element 71 is surrounded by the back gate guard ring 33. The protection switching element 71 includes a drain region 71D connected to the output pad 22. The protection switching element 71 includes a source region 71S, a gate wire 71G, and the back gate guard ring 33 that are connected to the ground pad 23.

The drain region 71D and the source region 71S of the protection switching element 71 and the second well region 32 form an NPN-type parasitic transistor 75. The parasitic transistor 75 includes a PN junction (parasitic diode) between the second well region 32 and the source region 71S and a PN junction (parasitic diode) between the second well region 32 and the drain region 71D. The parasitic transistor 75 includes a base connected to the back gate guard ring 33 by a resistor 76. The resistor 76 is formed of a resistance component of the second well region 32.

An ESD current may flow into the output pad 22. This produces a potential difference between the cathode and the anode of the parasitic diode formed of the drain region 71D of the protection switching element 71 and the second well region 32. When this happens, an ESD current flows to the base of the parasitic transistor 75 as indicated by arrow 72a. This current increases the base voltage of the parasitic transistor 75. The increase in the base voltage of the parasitic transistor 75 causes a current to flow toward the source region 71S of the protection switching element 71 as indicated by arrow 72b. As a result, the parasitic transistor 75 is switched on and allows current to flow from the drain region 71D to the source region 71S through the second well region 32 as indicated by arrow 72c. Thus, the protection switching element 71 is switched on to act as a protection element and allows the ESD current to flow from the output pad 22 through the protection switching element 71 to the ground pad 23, which is connected to the source region 71S.

### Semiconductor Device of First Embodiment

As shown in FIG. 5, the first drain regions 41D of the first switching elements 41 and the second drain regions 42D of the second switching elements 42 are connected to the output pad 22. Thus, the first switching elements 41 and the second switching elements 42 are used as protection switching elements that operate in the same manner against the ESD current applied to the output pad 22. As described above, of the first switching elements 41, the first switching element 41a that is located at the center in the Y-direction is the first driver switching element 14. The first switching elements 41 are each the first protection switching element 17a. The second switching elements 42 are each the second protection switching element 17b.

FIG. 6 is a schematic cross-sectional view taken along line F6-F6 shown in FIG. 5 showing operation of the first switching elements 41.

As shown in FIG. 6, the first switching elements 41 are arranged in the Y-direction. Each of the first switching elements 41 includes the first gate wire 41G, and the first source region 41S and the first drain region 41D located at opposite sides of the first gate wire 41G. The first source region 41S and the first drain region 41D of each first switching element 41 and the P-type second well region 32 form a parasitic transistor 45. Bases of the parasitic transistors 45 are connected to each other in the Y-direction by resistors 46, which are formed of resistance components of the second well region 32. The bases of the parasitic transistors 45 corresponding to the first switching elements 41a, which are located at opposite ends in the Y-direction, are connected to the back gate guard ring 33 by the resistors 46.

### Comparative Example of Semiconductor Device

A comparative example of a semiconductor device 10X, which is compared to the semiconductor device 10 of the first embodiment, will be described. Components of the semiconductor device 10X in the comparative example are the same as those of the semiconductor device 10 in the first embodiment and therefore assigned the same reference characters.

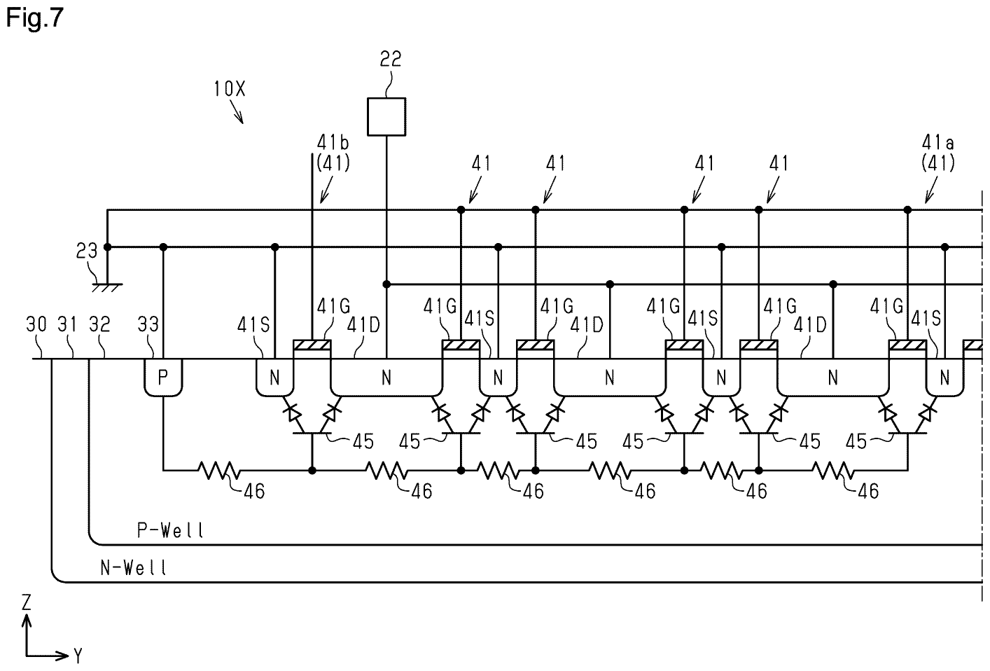

FIG. 7 is a cross-sectional view showing a portion of the semiconductor device 10X in the comparative example. In the semiconductor device 10X of the comparative example, the first gate wire 41G of the first end switching element 41b, which is located at an end in the Y-direction, is connected to the internal circuit 11 shown in FIG. 1. Thus, the first end switching element 41b, which is located at the end in the Y-direction, forms the first driver switching element 14 shown in FIGS. 1 and 2.

An ESD current may flow into the output pad 22 shown in FIG. 7. Such an ESD current flows from the output pad 22 toward the first drain region 41D. In this case, the first end switching element 41b forming the first driver switching element 14 shown in FIG. 2 may be activated before the other first switching elements 41 are activated. Such an instance will be described. The ESD current flows from the first drain region 41D of the first end switching element 41b to the base of the parasitic transistor 45, that is, the second well region 32, which is the back gate of the first end switching element 41b. The first end switching element 41b of the parasitic transistor 45 is located close to the back gate guard ring 33. Therefore, the resistance value between the base of the parasitic transistor 45 and the back gate guard ring 33 is lower than that of the remaining parasitic transistors 45. Hence, the base voltage of the remaining parasitic transistors 45 is less likely to be increased so that the remaining parasitic transistors 45 are less likely to be switched on. Therefore, when an ESD current flows to the second well region 32, the ESD current flows toward the first source region 41S of the first end switching element 41b through a parasitic transistor 45 that is switched on. That is, the ESD current concentrates on the parasitic transistor 45 of the first end switching element 41b. As a result, the first end switching element 41b, which is located at an end, may be damaged.

### Operation of Semiconductor Device of First Embodiment

The semiconductor device 10 of the first embodiment includes the first switching elements 41, which are arranged in the Y-direction and include the first gate wires 41G extending in the X-direction, and the back gate guard ring 33 surrounding the first switching elements 41. The first switching elements 41 are connected to each other in parallel and are connected between the output pad 22 and the ground pad 23. Of the first switching elements 41, at least one first switching element 41a located between the first end switching elements 41b located at opposite ends in the Y-direction forms the first driver switching element 14. The first gate wire 41G of the first switching element 41 excluding the first switching element 41a is connected to the ground pad 23 and forms the first protection switching element 17a.

As shown in FIG. 6, the first gate wire 41G of the first switching element 41a is connected to the internal circuit 11 shown in FIG. 1. Five first switching elements 41 are arranged between the first switching element 41a and the back gate guard ring 33. In the parasitic transistor 45 corresponding to each first switching element 41, the bases of the two parasitic transistors 45 located adjacent to each other in the Y-direction are connected to each other by the resistor 46, which is formed of a resistance component of the second well region 32.

An ESD current may flow into the output pad 22 shown in FIG. 6. The ESD current activates the first switching element 41a, which forms the driver switching element 14 shown in FIG. 2, before activating the other first switching elements 41. The ESD current flows from the first drain region 41D of the first switching element 41a to the base of the parasitic transistor 45, that is, the second well region 32, which is the back gate of the first switching element 41a. Between the parasitic transistor 45 and the back gate guard ring 33, other parasitic transistors 45 are located. This increases the base voltages of the parasitic transistors 45 located in the vicinity of the first switching element 41a. As a result, the parasitic transistors 45 are switched on. The ESD current flows through the parasitic transistors 45 that are switched on. This limits concentration of the ESD current on the parasitic transistor 45 of the first switching element 41a. As a result, damage to the first switching element 41a caused by concentration of the ESD current is limited. The ESD current will flow through the first switching elements 41 to the ground pad 23. Thus, the internal circuit 11 shown in FIG. 1 is protected.

As shown in FIG. 5, the first switching elements 41 are formed in a single second well region 32. The second switching elements 42 are also formed in the second well region 32 and arranged next to the first switching elements 41. As described above, the ESD current applied to the output pad 22 flows from the first drain region 41D of the first switching element 41a to the second well region 32.

The second switching elements 42 and the first switching elements 41 have the same configuration. Hence, the semiconductor device 10 includes parasitic transistors corresponding to the second switching elements 42. In the same manner as the parasitic transistor 45, when an ESD current increases the base voltage and causes the base current to flow, the parasitic transistors of the second switching elements 42 are switched on to allow the ESD current to flow. This further limits concentration of the ESD current on the parasitic transistor 45 of the first switching element 41a. As a result, damage to the first switching element 41a caused by concentration of the ESD current is limited. When the first switching element 41 and the second switching elements 42 are activated as a protection switching element, even if an excessive ESD current is applied to the output pad 22, the internal circuit 11 shown in FIG. 1 will be protected.

The first switching element 41a, which is located at the center in the Y-direction and forms the first driver switching element 14, has been described above with reference to FIG. 6. The first driver switching element 14 may be a first switching element 41 located between the two first end switching elements 41b, which are located at the opposite ends in the Y-direction. In an example, referring to FIG. 6, the first driver switching element 14 may be the first switching element 41 that is located adjacent to the first end switching element 41b. In this case, an ESD current flows to the first drain regions 41D of the first switching element 41 that is used as the first driver switching element 14. The ESD current flows to the first switching element 41 and the parasitic transistor 45 of an adjacent first switching element 41, which is, for example, the first end switching element 41b. This limits concentration of the current on the first switching element 41 forming the first driver switching element 14. As the first driver switching element 14 is arranged closer to the center of the first switching elements 41 in the Y-direction, the parasitic transistors 45 of a greater number of first switching elements 41 are activated by the ESD current. Thus, concentration of current on the first switching elements 41 is further limited.

The first switching elements 41 and the second switching elements 42, which form the first driver switching element 14 and the first protection element 17 (the first protection switching element 17a and the second protection switching element 17b) shown in FIGS. 1 and 2, have been described. The second driver switching element 15 and the second protection element 18, which are shown in FIGS. 1 and 3, are configured in the same manner as the first driver switching element 14 and the first protection element 17. Therefore, in the same manner, in the third switching elements and the fourth switching elements forming the second driver switching element 15 and the second protection element 18, concentration of an ESD current on a third switching element including a gate wire connected to the internal circuit 11 is limited. Accordingly, damage to the third switching element caused by concentration of the ESD current is limited. The third switching elements and the fourth switching elements are operated as a protection switching element to protect the internal circuit 11 shown in FIG. 1.

### Advantages

As described above, the first embodiment has the following advantages.

(1-1) The semiconductor device 10 includes the first switching elements 41, which are arranged in the Y-direction and include the first gate wires 41G extending in the X-direction, and the back gate guard ring 33 surrounding the first switching elements 41. The first switching elements 41 are connected to each other in parallel and are connected between the output pad 22 and the ground pad 23. Of the first switching elements 41, at least one first switching element 41a located between the first end switching elements 41b located at opposite ends in the Y-direction forms the first driver switching element 14. The first gate wires 41G of the first switching elements 41 excluding the first switching element 41a are connected to the ground pad 23. This forms the first protection switching elements 17a.

When an ESD current is applied to the output pad 22, the voltage of the second well region 32 is increased in the first switching element 41a, used as the first driver switching element 14, and other first switching elements 41 located in the vicinity of the first switching element 41a. As a result, the parasitic transistors 45 of the first switching element 41a and the first switching elements 41 located in the vicinity of the first switching element 41a are switched on and allow the ESD current to flow. This limits concentration of the current on the parasitic transistors 45 of the first switching elements 41.

(1-2) The first switching element 41a, which is located at the center in the Y-direction, forms the first driver switching element 14. As compared to a structure in which the first driver switching element 14 is located at an end of the first switching elements 41 in the Y-direction, an ESD current flows to the parasitic transistors 45 in a greater number of first switching elements 41. This further limits concentration of the current on the parasitic transistors 45 of the first switching elements 41.

(1-3) The first drain regions 41D of the first switching elements 41 are connected to the output pad 22. The first switching element 41a forming the first driver switching element 14 and other first switching elements 41 each function as a protection switching element. When an ESD current is applied to the output pad 22, the ESD current flows to the ground pad 23. Thus, the internal circuit 11 is protected.

(1-4) The semiconductor device 10 includes the second switching elements 42 surrounded by the back gate guard ring 33. The second gate wires 42G of the second switching elements 42 are connected to the ground pad 23. This forms the second protection switching element 17b. As described above, the first switching elements 41 and the second switching elements 42 each function as a protection switching element. With this configuration, when an excessive ESD current is applied to the output pad 22, the ESD current flows to the ground pad 23. Thus, the internal circuit 11 is protected.

(1-5) The second gate wire 42G of the second switching element 42 is greater in length than the first gate wire 41G of the first switching element 41. This increases the amount of current flowing to the second protection switching element 17b, which is formed of the second switching element 42. With this configuration, when an excessive ESD current is applied to the output pad 22, the ESD current flows to the ground pad 23. Thus, the internal circuit 11 is protected.

(1-6) The second gate wire 42G of the second switching element 42 is greater in length than the first gate wire 41G of the first switching element 41. In other words, the first gate wire 41G of the first switching element 41 is smaller in length than the second gate wire 42G of the second switching element 42. The length of the first gate wire 41G corresponds to the gate width of the first switching element 41 and determines the amount of current flowing through the first switching element 41. Because of the short first gate wire 41G, the first switching element 41a, used as the first driver switching element 14, sends a small amount of current from the output pad 22 toward the ground pad 23 in response to the output signal SO. Thus, the semiconductor device 10 uses a small amount of current, that is, has low power consumption, when operating an output signal.

### Second Embodiment

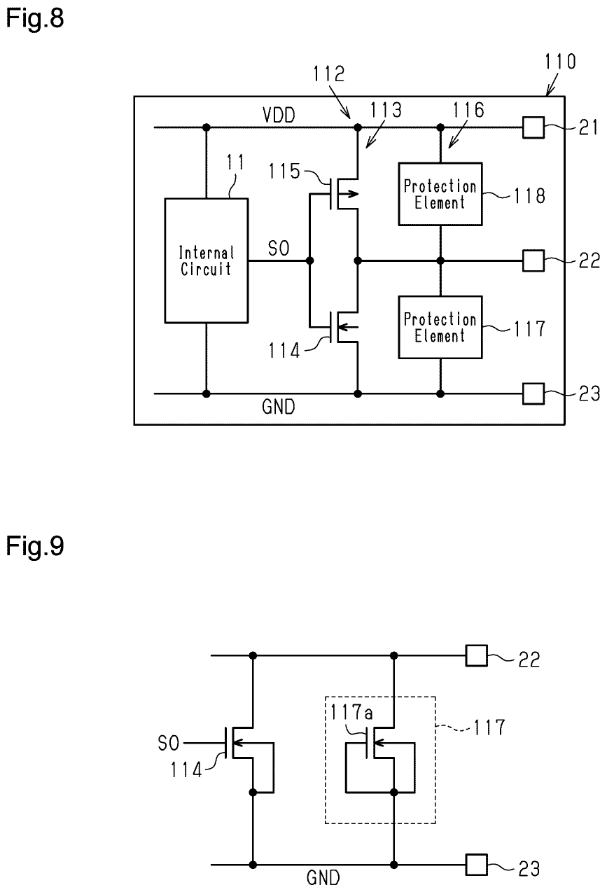

A second embodiment will now be described with reference to FIGS. 8 to 11.

In this embodiment, same reference characters are given to those components that are the same as the corresponding components of the first embodiment. Description of such components may be partially or entirely omitted.

### General Configuration of Semiconductor Device

As shown in FIG. 8, a semiconductor device 110 of the second embodiment includes the internal circuit 11 and an output circuit 112. The output circuit 112 includes an output buffer circuit 113 and a protection circuit 116.

The output buffer circuit 113 includes a first driver switching element 114 and a second driver switching element 115. The first driver switching element 114 and the second driver switching element 115 are each formed of a MOS transistor (MOSFET). In the second embodiment, the first driver switching element 114 is an NMOS transistor. In the second embodiment, the second driver switching element 115 is a PMOS transistor. In the second embodiment, the output buffer circuit 113 is a CMOS inverter circuit.

The first driver switching element 114 is connected between the output pad 22 and the ground pad 23. The first driver switching element 114 includes a source terminal connected to the ground pad 23. The first driver switching element 114 includes a drain terminal connected to the output pad 22. The first driver switching element 114 includes a gate terminal (control terminal) configured to receive an output signal SO.

The second driver switching element 115 is connected between the power pad 21 and the output pad 22. The second driver switching element 115 includes a source terminal connected to the power pad 21. The second driver switching element 115 includes a drain terminal connected to the output pad 22. The second driver switching element 115 includes a gate terminal (control terminal) configured to receive the output signal SO.

The protection circuit 116 includes a first protection element 117 and a second protection element 118. The first protection element 117 is connected between the output pad 22 and the ground pad 23. The second protection element 118 is connected between the power pad 21 and the output pad 22. The first protection element 117 and the second protection element 118 protect the internal circuit 11 from an ESD current flowing to the power pad 21 and the output pad 22.

FIG. 8 shows a single output pad 22, and the output buffer circuit 113 and the protection circuit 116 that are connected to the output pad 22. The semiconductor device 110 may include multiple output pads 22. The semiconductor device 110 may include one or more input pads. The semiconductor device 110 may be configured to receive a signal from the output pad 22. In this configuration, the output pad 22 is used as an input/output pad (I/O pad).

### Schematic Configuration of Driver Transistor and Protection Element

As shown in FIG. 9, the first driver switching element 114 is an NMOS transistor. The first driver switching element 114 is connected between the output pad 22 and the ground pad 23. The first driver switching element 114 includes a back gate terminal connected to the ground pad 23. That is, the back gate terminal of the first driver switching element 114 is connected to the source terminal of the first driver switching element 114.

The first protection element 117 includes a first protection switching element 117a. The first protection switching element 117a is an NMOS transistor. The first protection switching element 117a includes a source terminal connected to the ground pad 23. The first protection switching element 117a includes a drain terminal connected to the output pad 22. The first protection switching element 117a includes a gate terminal and a back gate terminal that are connected to the source terminal of the first protection switching element 117a.

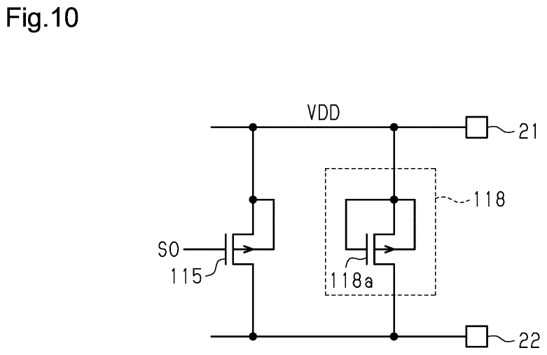

As shown in FIG. 10, the second driver switching element 115 is a PMOS transistor. The second driver switching element 115 is connected between the power pad 21 and the output pad 22. The second driver switching element 115 includes a back gate terminal connected to the power pad 21. That is, the back gate terminal of the second driver switching element 115 is connected to the source terminal of the second driver switching element 115.

The second protection element 118 includes a second protection switching element 118a. The second protection switching element 118a is a PMOS transistor. The second protection switching element 118a includes a source terminal connected to the power pad 21. The second protection switching element 118a includes a drain terminal connected to the output pad 22. The second protection switching element 118a includes a gate terminal and a back gate terminal connected to the source terminal of the second protection switching element 118a.

### Configuration of Driver Switching Element and Protection Switching Element

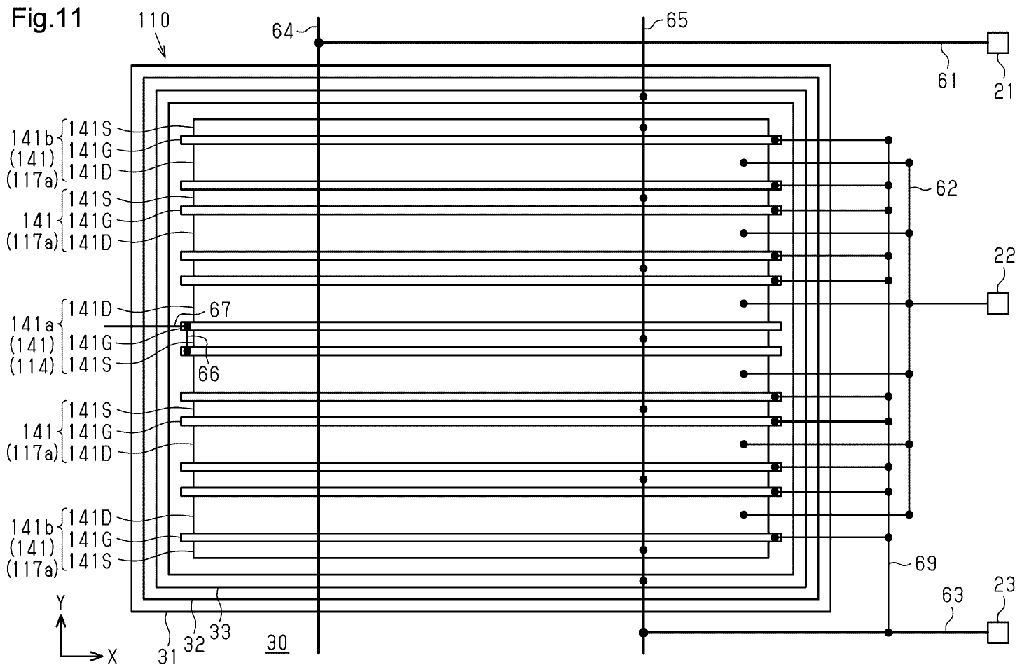

FIG. 11 is a plan view of a portion of the semiconductor device 110 showing a schematic structure of the first driver switching element 114 and the first protection element 117 (the first protection switching element 117a) shown in FIG. 9.

The semiconductor device 110 includes the semiconductor substrate 30. The first driver switching element 114 and the first protection element 117, which are shown in FIG. 8, are formed on the semiconductor substrate 30. More specifically, FIG. 11 is a plan view of the semiconductor substrate 30 taken in a thickness-wise direction. In FIG. 11, a solid line indicates a wire that connects an element or the like. A black dot indicates a contact.

The internal circuit 11, the second driver switching element 115, the second protection element 118, which are shown in FIG. 8, are formed on the semiconductor substrate 30 in the same manner as the first driver switching element 114 and the first protection element 117. In FIG. 11 and other drawings, the wires connecting elements and the contacts are shown in a simple manner.

FIG. 11 shows switching elements 141 that include the first driver switching element 114 and the first protection switching element 117a, which are shown in FIG. 9. The detail will be described below.

As shown in FIG. 11, the semiconductor device 110 includes the N-type first well region 31. As viewed in the Z-direction, the first well region 31 is rectangular and elongated in the X-direction. A P-type second well region 32 is formed in the first well region 31. As viewed in the Z-direction, the second well region 32 is rectangular and elongated in the X-direction. The P-type back gate guard ring 33 is formed in the second well region 32. As shown in the Z-direction, the back gate guard ring 33 has the form of a rectangular frame that is elongated in the X-direction. The back gate guard ring 33 is connected to the ground pad 23 by wires 65 and 63.

As shown in FIG. 11, the switching elements 141 are formed at an inner side of the back gate guard ring 33. The switching elements 141 are arranged in the Y-direction.

The switching elements 141 are formed of MOSFETs (NMOS transistors). Each of the switching elements 141 includes a gate wire 141G extending in the X-direction. Each of the switching elements 141 includes an N-type source region 141S and a drain region 141D located at opposite sides of the gate wire 141G. In two of the switching elements 141 located adjacent to each other in the Y-direction, the drain regions 141D are disposed so as to be continuous with each other. The gate wires 141G extend in the Y-direction in the range of the inner side of the back gate guard ring 33.

The drain regions 141D of the switching elements 141 are connected to the output pad 22 by the wire 62. The source regions 141S of the switching elements 141 are connected to the ground pad 23 by the wires 65 and 63.

The switching elements 141 include two first end switching elements 141b located at opposite ends of the switching elements 141 in the Y-direction. The first driver switching element 114 shown in FIG. 9 is formed of at least one of the switching elements 141 that are located between the two first end switching elements 141b. It is preferred that the first driver switching element 114 is formed of a switching element 141a located at the center in the Y-direction among the switching elements 114. In the second embodiment, the first driver switching element 114 is formed of two switching elements 141a that are located at the center in the Y-direction among the switching elements 141. The first driver switching element 114 may be formed of one or three or more switching elements 141.

The gate wires 141G of the two switching elements 141a are connected to each other by the wire 66 and connected to the internal circuit 11, shown in FIG. 8, by the wire 67.

The gate wires 141G of the switching elements 141 excluding the two switching elements 141a are connected to the ground pad 23 by the wires 69 and 63. Thus, excluding the two switching elements 141a, which form the first driver switching element 114, the switching elements 141 each form the first protection switching element 117a shown in FIG. 9.

In the example shown in FIG. 11, the first gate wires 141G of the two switching elements 141a are connected by the wires 66 and 67 to the internal circuit 11, which is shown in FIG. 8. The switching elements 141 have the same electrical characteristics. Thus, the number of switching elements 141 that are connected to the internal circuit 11 may be changed based on the design (layout) of the wires 66 and 67. The number of switching elements 141 connected to the internal circuit 11 corresponds to the amount of current flowing from the output pad 22 toward the ground pad 23. The amount of current corresponds to, for example, the number of elements that are connected to the output pad 22 and configured to be driven by the first driver switching elements 114. Thus, the switching elements 141 are configured to set the driving capacity of the first driver switching element 114 based on the number of switching elements 141 connected to the wires 66 and 67.

Examples of setting of driving capacity based on the number of switching elements 141a, other than the configuration shown in FIG. 11, will now be described. In a first example of the setting of driving capacity, for example, the first driver switching element 114 may be formed of a single switching element 141a connected to the wire 67. In a second example of the setting of driving capacity, the first driver switching element 114 may be formed of four switching elements 141a connected to the wires 66 and 67. By contrast, in the switching element 141 that is not connected to the wires 66 and 67, the gate wire 141G is connected to the ground pad 23. This forms the first protection switching element 117a. The switching element 141a, which is connected to the wires 66 and 67, is formed in the same second well region 32 as the other switching elements 141. Thus, the switching element 141a is used as a protection switching element. More specifically, the switching elements 141 are used as both the first driver switching element 114 and the first protection switching element 117a.

The first driver switching element 114 and the first protection element 117 (the first protection switching element 117a) shown in FIGS. 8 and 9 have been described. The second driver switching element 115 and the second protection element 118, which are shown in FIGS. 8 and 10, are configured in the same manner as the first driver switching element 114 and the first protection element 117. For example, the semiconductor device 110 includes third switching elements formed in an N-type third well region. The third well region and the third switching element are configured in the same manner as the second well region 32 and the first switching element 41, which are described above, except for conductive type.

### Operation

Operation of the semiconductor device 110 of the second embodiment will now be described.

As shown in FIG. 11, the switching elements 141 of the second embodiment are arranged in the Y-direction in the same manner as the first switching elements 41 of the first embodiment. Therefore, parasitic transistors of the switching elements 141 formed in the second well region 32 and resistors between the bases of the parasitic transistors are the same as the parasitic transistors 45 and the resistors 46 of the first switching elements 41 in the first embodiment. The first driver switching element 114 is formed of at least one of the switching elements 141 excluding the first end switching elements 141b, which are located at opposite ends of the switching elements 141 arranged in the Y-direction. With this configuration, when an ESD current is applied to the output pad 22, concentration of the current on the parasitic transistor of the switching element 141 forming the first driver switching element 114 is limited. Accordingly, damage to the switching element 141 caused by concentration of the ESD current will be limited.

The switching element 141 of the second embodiment includes the gate wire 141G that is greater in length than the first gate wire 41G of the first switching element 41 in the first embodiment. Accordingly, the gate width of the switching element 141 is greater than the gate width of the first switching element 41. Thus, the switching element 141 of the second embodiment allows a greater amount of current to flow than the first switching element 41 of the first embodiment. This provides the semiconductor device 110 including the first driver switching element 114 formed of the switching element 141 having a large driving capacity.

### Advantages

As described above, the second embodiment has the following advantages.

(2-1) The same advantages as the semiconductor device 10 of the first embodiment are obtained.

(2-2) The gate wires 141G of the switching elements 141 extend in the Y-direction in the range of the inner side of the back gate guard ring 33. Thus, the gate wire 141G of the second embodiment is greater in length than the first gate wire 41G of the first switching element 41 forming the first driver switching element 14 of the first embodiment. This provides the semiconductor device 110 having a greater driving capacity than the semiconductor device 10 of the first embodiment.

### Modified Examples

The embodiments may be modified, for example, as follows. The modified examples described below may be combined as long as there is no technical contradiction. In the following modified examples, the same reference characters are given to those components that are the same as the corresponding components of the above embodiments. Such components will not be described in detail.

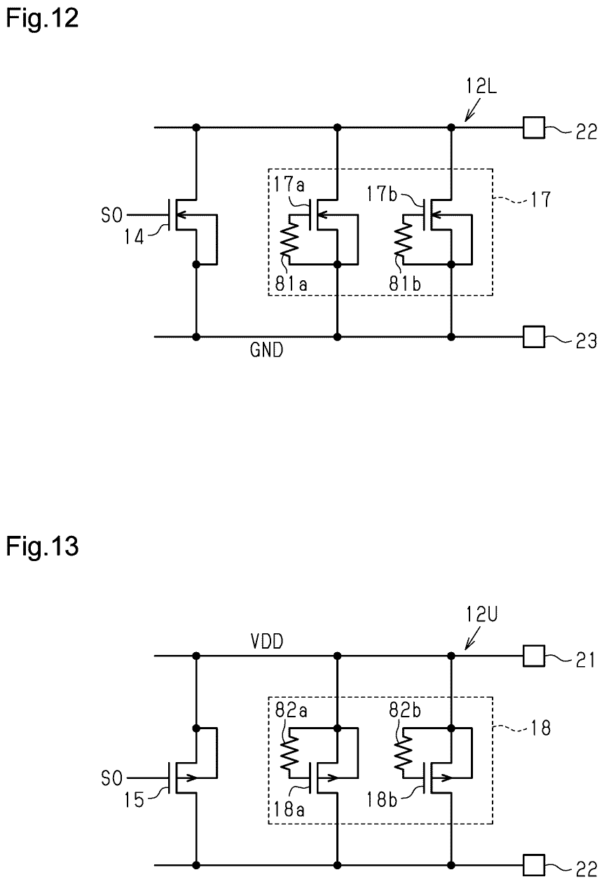

As shown in FIG. 12, the gate terminal of the first protection switching element 17a, forming the first protection element 17, may be connected to the source terminal of the first protection switching element 17a by a resistor 81a. The gate terminal of the second protection switching element 17b, forming the first protection element 17, may be connected to the source terminal of the second protection switching element 17b by a resistor 81b.

As shown in FIG. 13, the gate terminal of the third protection switching element 18a, forming the second protection element 18, may be connected to the source terminal of the third protection switching element 18a by a resistor 82a. The gate terminal of the fourth protection switching element 18b, forming the second protection element 18, may be connected to the source terminal of the fourth protection switching element 18b by a resistor 82b.

In the first embodiment, the semiconductor device 10 includes the output buffer circuit 13 having a CMOS structure. Alternatively, the second driver switching element 15 between the power pad 21 and the output pad 22 may be omitted from the output circuit (open drain output circuit). In this configuration, the second protection element 18 may be omitted. The semiconductor device 110 of the second embodiment may be changed in the same manner.

In the embodiments described above, the semiconductor devices 10 and 110 are configured to output the output signal OUT to the output pad 22. Instead, the output pad 22 may be configured to receive a signal and output a signal, that is, configured to be an input/output pad (I/O pad).

Referring to FIG. 2, the gate terminal of the first protection switching element 17a and the second protection switching element 17b may be connected to the output pad 22, that is, the drain terminal, to form diode connection. Also, referring to FIG. 3, the gate terminal of the third protection switching element 18a and the fourth protection switching element 18b may be connected to the output pad 22, that is, the drain terminal, to form diode connection. In the same manner, referring to FIG. 9, the gate terminal of the first protection switching element 117a may be connected to the output pad 22, that is, the drain terminal, to form diode connection. Referring to FIG. 10, the gate terminal of the second protection switching element 118a may be connected to the output pad 22, that is, the drain terminal, to form diode connection.

### Clauses

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

[Clause 1] A semiconductor device, including:
first switching elements (41) formed of a MOSFET and arranged in a first direction and, the first switching elements (41) each including a first gate wire (41G) extending in a second direction that intersects the first direction; and
a back gate guard ring (33) surrounding the first switching elements (41), in which
the first switching elements (41) include three or more first switching elements,
the first switching elements (41) are connected to each other in parallel and connected between a first pad (22) and a second pad (23),
the first switching elements (41) include a driver switching element, the driver switching element being at least one first switching element (41a) located between two first end switching elements (41b) located at opposite ends of the first switching elements (41) in the first direction, and
the first switching elements (41) excluding the driver switching element (41a) include a first protection switching element, the first gate wire (41G) of the first protection switching element being connected to the first pad (22) or the second pad (23).

[Clause 2] The semiconductor device according to clause 1, in which the driver switching element is the first switching element (41a) arranged in a center of the first direction.

[Clause 3] The semiconductor device according to clause 1 or 2, in which the driver switching element is less in number than the first protection switching element.

[Clause 4] The semiconductor device according to any one of clauses 1 to 3, including:
second switching elements (42) arranged next to the first switching elements (41) in the second direction and formed of a MOSFET, the second switching elements (42) being arranged in the first direction and each including a second gate wire (42G) extending in the second direction, in which
the back gate guard ring (33) surrounds the first switching elements (42) and the second switching elements (42),
the second switching elements (42) are equal in number to the first switching elements (41), and
the second switching elements (42) includes a second protection switching element, the second gate wire (42G) of the second protection switching element being connected to the first pad (22) or the second pad (23).

[Clause 5] The semiconductor device according to clause 4, in which
the first switching elements (41) and the second switching elements (42) each include an N-channel MOSFET,
the first pad (22) is an output pad, and
the second pad (23) is a ground pad.

[Clause 6] The semiconductor device according to clause 4, in which
the first switching elements (41) and the second switching elements (42) each include a P-channel MOSFET,
the first pad (22) is an output pad, and the second pad (21) is a power pad.

[Clause 7] The semiconductor device according to any one of clauses 4 to 6, in which the second gate wire (42G) is greater in length than the first gate wire (41G).

[Clause 8] The semiconductor device according to any one of clauses 4 to 7, in which the first gate wire (41G) is arranged next to the second gate wire (42G) in the second direction.

[Clause 9] The semiconductor device according to any one of clauses 4 to 8, in which the first switching elements (41) and the second switching elements (42) each include a back gate terminal connected to the second pad (23).

[Clause 10] The semiconductor device according to any one of clauses 4 to 9, in which the first switching elements (41) and the second switching elements (42) are formed in a single well region (32).

[Clause 11] The semiconductor device according to any one of clauses 1 to 10, further including
a resistive element (81a) connected between the first gate wire (41G, 141G) of the protection switching elements (41, 141) and the first pad (22) or the second pad (21, 23).

[Clause 12] The semiconductor device according to any one of clauses 1 to 11, in which the second pad includes a first power pad (23) and a second power pad (21), the semiconductor device, further including:
a first transistor (14, 114) and a first protection element (17, 117) connected between the first power pad (23) and the first pad (22); and
a second transistor (15, 115) and a second protection element (18, 118) connected between the first pad (22) and the second power pad (21), in which
the first transistor (14, 114) and the second transistor (15,115) each include the driver switching elements, and
the first protection element (17, 117) and the second protection element (18, 118) each include the first protection switching element (17a, 117a).

[Clause 13] The semiconductor device according to clause 12, in which
the first transistor (14, 114) is formed of an N-channel MOSFET, and
the second transistor (15, 115) is formed of a P-channel MOSFET.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

### REFERENCE SIGNS LIST

10 semiconductor device
11 internal circuit
12 output circuit
12L first output circuit
12U second output circuit
13 output buffer circuit
14 first driver switching element
15 second driver switching element
16 protection circuit
17 first protection element
17a first protection switching element
17b second protection switching element
18 second protection element
18a third protection switching element
18b fourth protection switching element
21 power pad
22 output pad
23 ground pad
30 semiconductor substrate
31 first well region
32 second well region
33 back gate guard ring
41 first switching element
41a first switching element
41b first end switching element
41D first drain region
41G first gate wire
41S first source region
42 second switching element
42D second drain region
42G second gate wire
42S second source region
45 parasitic transistor
46 resistor
61 to 69 wire
71 protection switching element
71D drain region
71G gate wire
71S source region
72a to 72c arrow
75 parasitic transistor
76 resistor
81a resistor
81b resistor
82a resistor
82b resistor
110 semiconductor device
112 output circuit
113 output buffer circuit
114 first driver switching element
115 second driver switching element
116 protection circuit
117 first protection element
117a first protection switching element
118 second protection element
118a second protection switching clement
141 switching element
141a switching element
141b first end switching element
141D drain region
141G gate wire
141S source region
OUT output signal
SO output signal
VDD power voltage

1. A semiconductor device, comprising:
first switching elements formed of a MOSFET and arranged in a first direction, the first switching elements each including a first gate wire extending in a second direction that intersects the first direction; and
a back gate guard ring surrounding the first switching elements, wherein
the first switching elements include three or more first switching elements,
the first switching elements are connected to each other in parallel and connected between a first pad and a second pad,
the first switching elements include a driver switching element, the driver switching element being at least one first switching element located between two first end switching elements located at opposite ends of the first switching elements in the first direction, and
the first switching elements excluding the driver switching element include a first protection switching element, the first gate wire of the first protection switching element being connected to the first pad or the second pad.

2. The semiconductor device according to claim 1, wherein the driver switching element is the first switching element arranged in a center of the first direction.

3. The semiconductor device according to claim 1, wherein the driver switching element is less in number than the first protection switching element.

4. The semiconductor device according to claim 1, comprising:
second switching elements arranged next to the first switching elements in the second direction and formed of a MOSFET, the second switching elements being arranged in the first direction and each including a second gate wire extending in the second direction, wherein
the back gate guard ring surrounds the first switching elements and the second switching elements,
the second switching elements are equal in number to the first switching elements, and
the second switching elements include a second protection switching element, the second gate wire of the second protection switching element being connected to the first pad or the second pad.

5. The semiconductor device according to claim 4, wherein
the first switching elements and the second switching elements each include an N-channel MOSFET,
the first pad is an output pad, and
the second pad is a ground pad.

6. The semiconductor device according to claim 4, wherein
the first switching elements and the second switching elements each include a P-channel MOSFET,
the first pad is an output pad, and
the second pad is a power pad.

7. The semiconductor device according to claim 4, wherein the second gate wire is greater in length than the first gate wire.

8. The semiconductor device according to claim 4, wherein the first gate wire is arranged next to the second gate wire in the second direction.

9. The semiconductor device according to claim 4, wherein the first switching elements and the second switching elements each include a back gate terminal connected to the second pad.

10. The semiconductor device according to claim 4, wherein the first switching elements and the second switching elements are formed in a single well region.
